(19) United States
(12) Patent Application Publication
(10) Pub. No.: US 2011/0291150 A1
(43) Pub. Date: Dec. 1, 2011

(54) LED ILLUMINATION DEVICE

(75) Inventors: Chung-Jen Lin, Taipei (TW); Yun-Lin Peng, Hsinchu County (TW)

(73) Assignee: NEOBULB TECHNOLOGIES, INC., Bandar Seri Begawan (BN)

(21) Appl. No.: 13/114,350

(22) Filed: May 24, 2011

(30) Foreign Application Priority Data
May 25, 2010 (TW) 099116614

(51) Int. Cl. H01L 33/64

(52) U.S. Cl. 257/99; 257/E33.058

(57) ABSTRACT

The invention disclose a light emitting diode (LED) illustration device, comprising a platform, a substrate and a light emitting diode die. The said platform comprises an upper surface and a bottom surface. A first concave portion is formed on the upper surface of the platform, and a second concave portion is formed on the bottom surface of the platform. The first concave portion is connected with the second concave portion. The substrate is embedded in the second concave portion, wherein the said substrate comprises an electrostatic discharge protection structure. The said light emitting diode die is disposed on the said substrate.

### BACKGROUND OF THE INVENTION

1. Field of the Invention

The present invention relates to a light emitting diode (LED) illustration device. More particularly, the present invention relates to a semiconductor illustration device package structure for packaging at least one semiconductor light emitting diode die. Additionally, the invention relates to a substrate comprising an electrostatic protection structure, at least one semiconductor light emitting diode dies can emit light with different colors for display devices and illustration devices.

2. Description of the Prior Art

With the development of semiconductor light emitting devices, a light-emitting diode (LED), which has several advantages such as power save, seismic resistance, quick reaction, and so on, becomes a new light source. In order to raise the intensity of light, high-power LED has been used as the light source in many illumination products. Although high-power LED can provide stronger light, it may also cause other problems related to heat dissipation.

Generally, LED is disposed on a substrate. The substrate is disposed on a heat dissipation device. The heat dissipation device can be a metal plate, a heat pipe or other materials with high thermal conductive efficiency. The heat dissipation device has a plurality of fins to increase the efficiency of heat dissipation. However, the heat generated by LED will be conducted to the heat dissipation device though the substrate. Thus, the interface thermal resistances of LED and the substrate, the substrate heat dissipation device will become important. In prior art, LED is small and formed or fixed on the substrate, the improvement of the interface thermal resistance is limited. The improvement of the system is focused on the interface thermal resistance of the substrate and heat dissipation device.

The substrate must not be fixed to the heat dissipation device tightly, so that a lot of gas chambers will exist. Because each gas chamber is too small to convect the heat, the heat is transferred by conducting mainly. Because the thermal conductivity coefficient of the air is too small, the interface thermal resistance of the substrate and the heat dissipation device will be high. In prior art, the heat dissipation paste may be filled between the substrate and the heat dissipation device to remove the gas chamber for decreasing the interface thermal resistance. However, long-term high temperature will cause aging effect to the heat dissipation paste, so that the flowability of the heat dissipation paste will decrease. Thus, the gas chamber will be generated and the interface thermal resistance will increase. Furthermore, the heat dissipation device cannot conduct or dissipate the heat, LED will break.

Accordingly, a LED illustration device shall be provided to prove the problem in prior art. Additionally, with the development of semiconductor, the size of electronic device becomes smaller and smaller. Thus, many problems will be caused because of the size reduction, such as electrostatic discharge (ESD).

In a dry environment, the electrostatic accumulated in human body can be 2000˜3000 V. If people touch LED carelessly, LED will deteriorate or break. Thus, the quality and yield of LED will be affected, so that the cost problem of LED will become worse. In prior art, LED and a zener diode are parallel for increasing the electrostatic protection ability of LED. Please refer to FIG. 1. FIG. 1 illustrates a schematic diagram of a parallel connection of the LED Z4 and a zener diode Z 1 . The circuit is operated with a normal operating voltage.

Please refer to FIG. 1 again. FIG. 1 illustrates a design of an electrostatic protection structure of a LED according to the prior art. As shown in FIG. 1, an insulating region exists between a first electrode and a second electrode. The zener diode is disposed in the first electrode and connected to the second electrode by a gold wire to form a circuit. Additionally, the LED exists in the circuit between the first electrode and the second electrode.

When normal, the zener diode is not conductive and the electric power does not be consumed. When the transient high pressure electrostatic is generated, the LED Z4 and the zener diode Z1 are turn-on. However, because the voltage is higher than the breakdown voltage of the zener diode Z1, the resistance of the zener diode Z1 is highly lower than the internal resistance of the LED Z4. Thus, let the electric current pass though the e zener diode Z1 to control the steady operating voltage for protecting the LED Z4.

To achieve the ability of the electrostatic protection, the different package structures appeared, such as the U.S. Pat. No. 6,054,716 “Semiconductor light emitting device having a protecting device” and the U.S. Pat. No. 6,333,522 “Light-emitting element, semiconductor light emitting device, and manufacturing methods therefore”.

However, because the size of the zener diode is small, the demand for the tolerance of the machine becomes higher when the zener diode is fixed on the electrode. Thus, the cost will increase.

To sum up, the present invention is to provide a LED module integrated with an electrostatic discharge protection structure. The electrostatic discharge protection structure can be integrated into a silicon substrate or integrated into the LED module by other ways to prevent the LED die from breaking by the static surge.

### SUMMARY OF THE INVENTION

A scope of the invention is to provide a light emitting diode (LED) illustration device to prevent the LED die from breaking by the static surge.

According to an embodiment, the LED illustration device comprises a platform, a substrate and a light emitting diode die. The platform comprises an upper surface and a bottom surface. A first concave portion is formed on the upper surface of the platform, and a second concave portion is formed on the bottom surface of the platform. The first concave portion is connected to the second concave portion. The substrate is embedded in the second concave portion, wherein the substrate comprises an electrostatic discharge protection structure. The LED die is disposed on the said substrate.

In practice, the diameter of the connecting portion between the first concave portion and second concave portion is smaller than the diameter of the second concave portion, so that the second concave portion has a top. The substrate is connected to the top. The substrate has a lower surface. The lower surface of the substrate and the bottom surface of the platform are almost coplanar. The platform is a cryogenic cofiring ceramic plate, a printed circuit board or a metal core circuit board. The substrate is made by semiconductor materials, such as silicon. Additionally, the substrate comprises a reflecting layer disposed on the first concave portion. Furthermore, the electrostatic discharge protection structure is formed by doping.

In practice, the LED illustration device further comprises a heat conductive element. The heat conductive element can be a heat pipe or a heat pillar. Additionally, the LED illustration device further comprises a support body. The support body comprises at least one hole for fixing the support body on the heat conductive element. The LED illustration device further comprises a heat conductive phase change material disposed between the flat portion and the substrate. Furthermore, the LED illustration device further comprises a glue filled between the second concave portion and the substrate.

The advantage and spirit of the invention may be understood by the following recitations together with the appended drawings.

### BRIEF DESCRIPTION OF THE APPENDED DRAWINGS

FIG. 1 illustrates a schematic diagram of a light emitting diode module according to an embodiment of the prior art.

FIG. 2 illustrates a schematic diagram of the light emitting diode module according to an embodiment of the invention.

FIG. 3 illustrates a schematic diagram of the light emitting diode module according to an embodiment of the invention.

FIG. 4 illustrates an element combination diagram of the light emitting diode module according to an embodiment of the invention.

FIG. 5 illustrates a schematic diagram of the platform of the light emitting diode module according to another embodiment of the invention.

FIG. 6 illustrates a schematic diagram of the platform of the light emitting diode module according to another embodiment of the invention.

FIG. 7 illustrates a schematic diagram of the platform of the light emitting diode module according to another embodiment of the invention.

FIG. 8 illustrates a schematic diagram of the substrate of the light emitting diode module according to another embodiment of the invention.

FIG. 9 illustrates an element decomposition diagram of the light emitting diode module according to another embodiment of the invention.

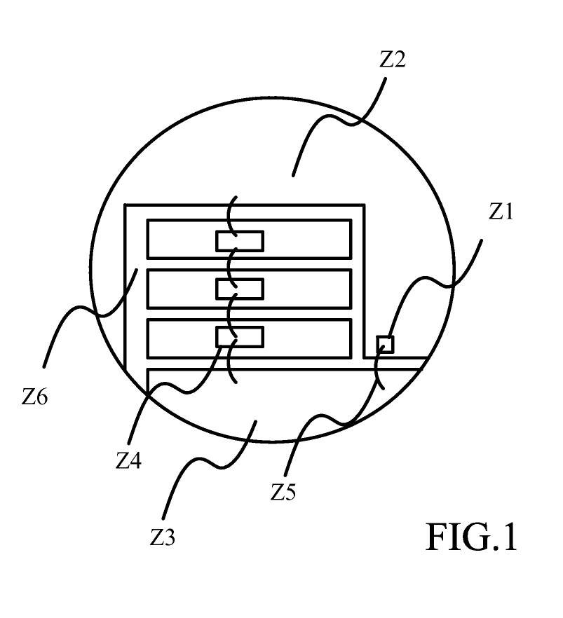

### DETAILED DESCRIPTION OF THE INVENTION

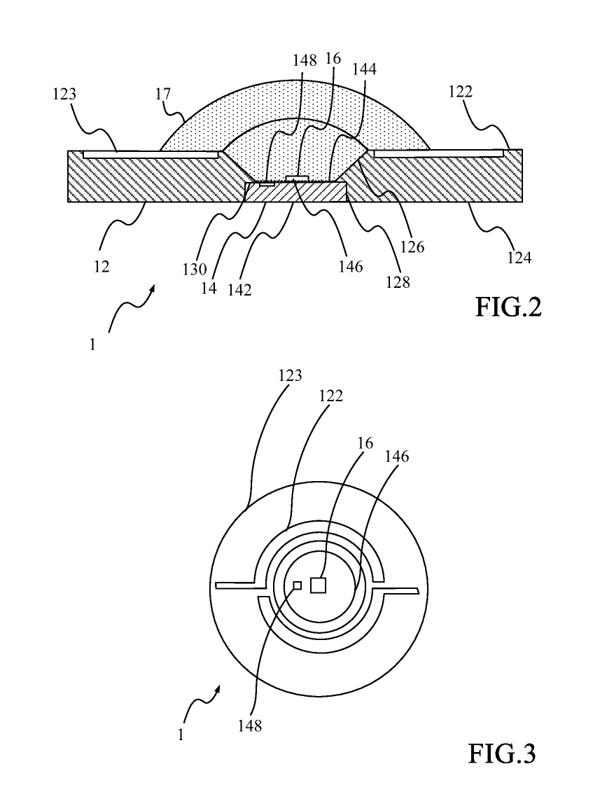

Please refer to FIG. 2 and FIG. 3. FIG. 2 and FIG. 3 illustrate a schematic diagram of a light emitting diode (LED) illustration device 1 according to an embodiment of the invention. As shown in FIG. 3, the LED illustration device 1 comprises a platform 12, a substrate 14, a package material 17 and a light emitting diode die 16.

The platform 12 comprises an upper surface 122 and a bottom surface 124. A first concave portion 126 is formed on the upper surface 122 of the platform 12. A second concave portion 128 is formed on the bottom surface 124 of the platform 12. The first concave portion 126 is connected to the second concave portion 128. Additionally, the direction of the surface of the upper surface 122 and the bottom surface 124 are reverse.

The diameter of the connecting portion between the first concave portion 126 and second concave portion 128 is smaller than the outer diameter of the second concave portion 128. Thus, the second concave portion 128 has a top 130, the substrate 14 is connected to the top 130.

Furthermore, the platform 12 can be a cryogenic cofiring ceramic plate, a printed circuit board 123, a metal core circuit board 123 or other materials which can be connected to the substrate 14.

In the embodiment, a circuit 123 is formed on the upper surface 122 of the platform 12. The circuit 123 is electronically connected to the electrostatic discharge protection structure 148 and the light emitting diode die 16 by a gold wire to form a parallel circuit 123. However, the gold wire must not to be used necessarily, according to the differences of the light emitting diode dies 16, the gold wire can be omitted. For example, when the electrostatic discharge protection structure 148 is formed in the substrate 14 and the light emitting diode die 16 is a stack die, the die can be directly disposed on the electrostatic discharge protection structure 148 of the substrate 14. That is to say, the manufacturing process of the gold wire can be omitted.

In the embodiment, the substrate 14 is embedded in the second concave portion 128 of the platform 12. The substrate 14 is connected to the top 130 of the platform 12. The top 130 holds the substrate 14 to increase the area between the substrate 14 and the second concave portion 128. Additionally, a glue (not shown in figures) can be filled between the substrate 14 and the second concave portion 128 of the platform 12 to let the substrate 14 be connected to the second concave portion 128 tightly. Furthermore, depending on the design, the substrate 14 can be made by silicon, materials integrated with a semiconductor structure or other materials used in prior art.

In the embodiment, the substrate 14 comprises a loading portionc146 and a lower surface 142, the direction of the lower surface 142 and the surface of the loading portion 146 are reverse. The lower surface 142 and the bottom surface 124 of the platform 12 are almost coplanar. The surface of the substrate 14 can comprises the plurality of loading portions 146. At least one light emitting diode die 16 is loaded by the surface of each loading portion 146.

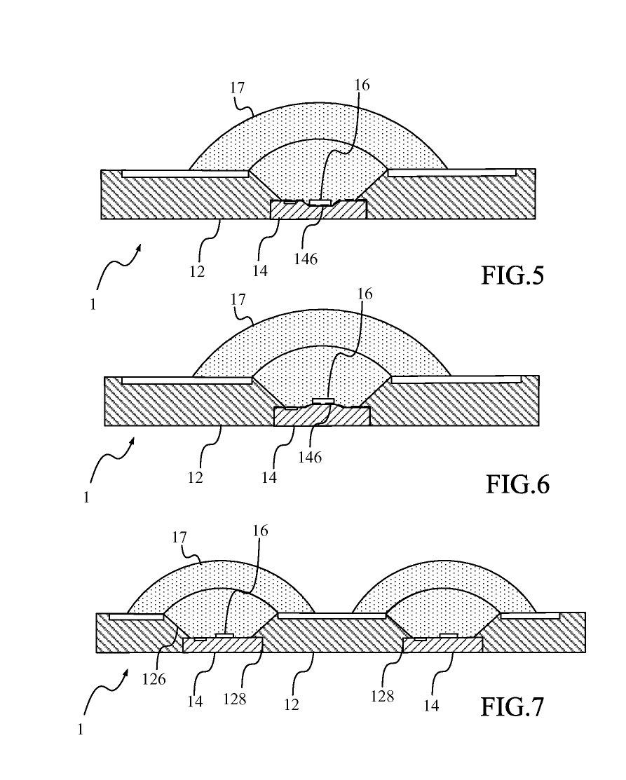

In the embodiment, the horizontal height of the loading portion 146 is almost equal to the horizontal height of the connecting surface between the substrate 14 and the top 130. Additionally, the horizontal height of the loading portion 146 can also be higher or lower than the horizontal height of the connecting surface between the substrate 14 and the top 130 to form a concave structure or a convex structure separately. The concave structure is shown in FIG. 5 and the convex structure is shown in FIG. 6. The features shown in FIG. 5 and FIG. 6 are similar to the features shown in FIG. 2 and it will no longer be explained.

Please refer to FIG. 2 again, the surface of the loading portion 146 is coated with a reflecting layer 144 (shown in dotted line) for reflecting the light emitted from the light emitting diode die 16. The number of the light emitting diode die 16 disposed on the loading portion 146 can be adjusted.

In the embodiment, the electrostatic discharge protection structure 148 is integrated in the substrate 14. By doping with different components and densities, the p-type semiconductors and the n-type semiconductors can be formed in the substrate 14. The electrostatic discharge protection structure 148 does not be integrated into the substrate 14 necessarily and the varieties of the electrostatic discharge protection structure 148 will no longer be explained.

The electrostatic discharge protection structure 148 can be displaced by an electrostatic discharge protection die disposed independently or a packaged electrostatic discharge protection module. The electrostatic discharge protection die can be a zener diode bare chip disposed independently. The packaged electrostatic discharge protection module can be a surface mounting module. The surface mounting module comprises at least one electrostatic discharge protection die, wherein the electrostatic discharge protection die can be a zener diode die.

When the electrostatic discharge protection structure 148 runs normally, the electrostatic discharge protection structure 148 is not conductive and the electric power does not be consumed. When the transient high pressure electrostatic is generated, the light emitting diode die 16 and the electrostatic discharge protection structure 148 are turn-on. However, because the voltage is higher than the breakdown voltage of the electrostatic discharge protection structure 148, the resistance of the electrostatic discharge protection structure 148 is highly lower than the internal resistance of the LED 16. Thus, let the electric current pass though the electrostatic discharge protection structure 148 to control the steady operating voltage for protecting the LED 16.

Please refer to FIG. 2 again, in the embodiment, the light emitting diode die 16 comprises the light emitting diode dies with any type or laser diode dies.

The LED illustration device 1 further comprises a package material 17 filled in the first concave portion 126 or disposed on the upper surface 122 of the platform 12. The package material 17 is used to protect the light emitting diode die 16 and the gold wire (not shown in figures). The package material 17 does not be filled in the full first concave portion 126 necessarily.

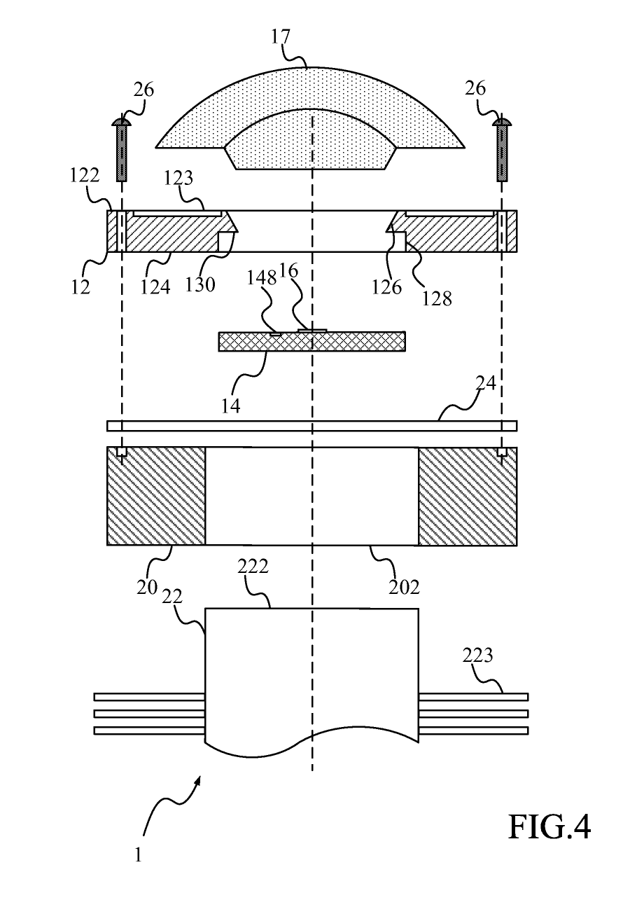

FIG. 4 illustrates an element combination diagram of the light emitting diode module according to an embodiment of the invention. In the embodiment, the LED illustration device 1 further comprises a support body 20 and a heat conductive element 22.

The central part of the support body 20 comprises at least one hole for fixing the support body 20 on the heat conductive element 22. The diameter of the hole 202 is almost equal to the diameter of the heat conductive element 22 for providing a friction to fix the support body 20 on the heat conductive element 22. The surface of the support body 20 can be designed with a plurality of threaded holes for fixing other structures on the surface of the support body 20.

The heat conductive element 22 can comprises a flat portion 222 and a plurality of fins 223. In the embodiment, the flat portion 222 is located at an extremity of the heat conductive element 22. The horizontal direction of the surface of the flat portion 222 and the extension direction of the extremity of the heat conductive element 22 are parallel. According to the design, the flat portion 222 can be any flat surface of the heat conductive element 22. The flat portion 222 of the heat conductive element 22 is connected to the substrate 14 tightly.

The plurality of fins of the heat conductive element 22 is disposed on a surface of the heat conductive element 22. In the embodiment, the fins 223 are perpendicular to the extension direction of the heat conductive element 22 for dissipating the heat generated by the flat portion 222. The heat conductive element 22 can be a heat pipe or a heat pillar or other strip heat dissipation devices.

A gap maybe exists between the flat portion 222 of the heat conductive element 22 and the substrate 14 to decrease the interface thermal resistance between the substrate 14 and flat portion 222 by filling a heat conductive phase change material 24.

According to a preferred embodiment, the heat conductive phase change material 124 has a transition temperature between 40° C. to 60° C. After phase transformation, the flowability of the heat conductive phase change material 24 will increase for filling between the substrate 14 and flat portion 222 easily. Additionally, a gas chamber will not be generated and the heat generated by the light emitting diode die 16 will be removed though the heat conductive element 22.

In the embodiment, the thermal conductivity of the heat conductive phase change material 124 can be, but not limit to between 3.6 W/mK to 4.0 W/mK. Additionally, the adhesion of the heat conductive phase change material 24 helps the substrate 14 for mounting on the flat portion 222.

Please refer to FIG. 4 again. The platform 12 is fixed on the surface of the support body 20 by screws. Additionally, the surface, between the support body 20 and the platform 12, and the flat portion 222 of the heat conductive element 22 are almost coplanar.

The substrate 14 is embedded in the second concave portion 128. The platform 12 holds the substrate 14 and fixes substratel4 on the flat portion 222 of the heat conductive element 22 by applying a pressure to the substrate 14.

To be supplemented, the way of fixing the platform 12 by the support body 20 does not limit in FIG. 4. The platform 12 can also be fixed on the support body 20 by a mechanism. Additionally, the said two ways can be applied at the same time.

Please refer to FIG. 7. FIG. 7 illustrates a LED module comprises a platform 12 comprising a plurality of first concave portions 126 and a plurality of second concave portions 128. Additionally, a substrate 14 is embedded in each second concave portion 128 correspondingly to increase the light emission quantity per unit area. In the embodiment, two substrates 14 are embedded in each platform 12. The features shown in FIG. 7 are similar to the features shown in FIG. 7 and it will no longer be explained.

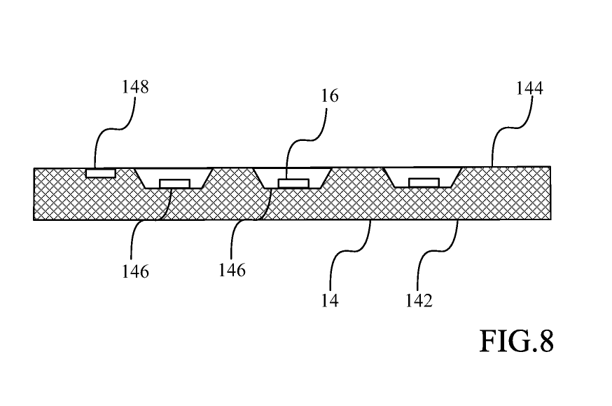

Please refer to FIG. 8. FIG. 8 illustrates a substrate 14 of a LED module of the invention. The substrate 14 comprises a plurality of loading portions 146. In the embodiment, each loading portion 146 is a concave structure. The features shown in FIG. 8 are similar to the features shown in FIG. 3 and it will no longer be explained.

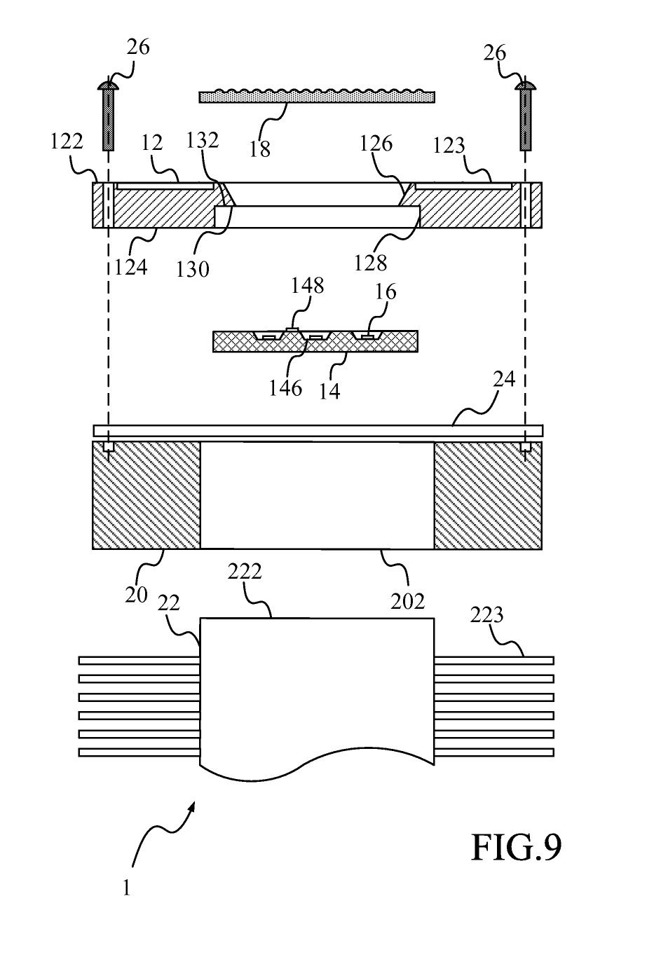

Please refer to FIG. 9. FIG. 9 illustrates an element decomposition diagram of the light emitting diode module according to another embodiment of the invention. According to the preferred embodiment, the features are almost similar to the said embodiment. However, in the embodiment, the LED illustration device comprises a micro lens. A package material (not shown in figures) is disposed between the light emitting diode die 16 and the micro lens and covers the light emitting diode die 16. Additionally, the electrostatic discharge protection structure 148 is a electrostatic discharge protection die. The features shown in FIG. 9 are similar to the features shown in FIG. 5 and it will no longer be explained.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A light emitting diode illustration device, comprising:
a platform comprising an upper surface and a bottom surface, a first concave portion formed on the upper surface of the platform, a second concave portion formed on the bottom surface of the platform, wherein the first concave portion is connected to the second concave portion;
a substrate embedded in the second concave portion, wherein the substrate comprises an electrostatic discharge protection structure and a loading portion; and
a light emitting diode die disposed on the substrate;
wherein the electrostatic discharge protection structure is electronically connected to the platform, the substrate and the light emitting diode die.

2. The light emitting diode illustration device of claim 1, wherein the diameter of the connecting portion between the first concave portion and second concave portion is smaller than the diameter of the second concave portion, so that the second concave portion has a top, the substrate is connected to the top.

3. The light emitting diode illustration device of claim 2, wherein the horizontal height of the loading portion is higher or lower than the horizontal height of the connecting surface between the substrate and the top.

4. The light emitting diode illustration device of claim 1, wherein the substrate has a lower surface, the lower surface of the substrate and the bottom surface of the platform are almost coplanar.

5. The light emitting diode illustration device of claim 1, wherein the platform is a cryogenic cofiring ceramic plate, a printed circuit board or a metal core circuit board.

6. The light emitting diode illustration device of claim 1, wherein the electrostatic discharge protection structure is a zener diode die which is disposed singly.

7. The light emitting diode illustration device of claim 1, wherein the electrostatic discharge protection structure is formed by doping.

8. The light emitting diode illustration device of claim 1, further comprising a heat conductive element, the heat conductive element having a flat portion for placing the substrate.

9. The light emitting diode illustration device of claim 8, wherein the heat conductive element is a heat pipe or a heat pillar.

10. The light emitting diode illustration device of claim 8, further comprising a support body, the support body comprising at least one hole for fixing the support body on the heat conductive element.

11. The light emitting diode illustration device of claim 8, further comprising a heat conductive phase change material disposed between the flat portion and the substrate.

12. The light emitting diode illustration device of claim 1, further comprising a glue filled between the second concave portion and the substrate.
